(19) United States
(12) Patent Application Publication
(10) Pub. No.: US 2007/0200232 A1
(43) Pub. Date: Aug. 30, 2007

(54) Printed-wiring board with built-in component, manufacturing method of printed-wiring board with built-in component, and electronic device

(76) Inventors: Daigo Suzuki, Yokohama-shi (JP); Akihiko Happoya, Fussa-shi (JP); Jun Karasawa, Tokyo (JP); Hidenori Tanaka, Hachioji-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/711,558

(22) Filed: Feb. 27, 2007

(30) Foreign Application Priority Data
Feb. 28, 2006 (JP) 2006-051527

(51) Int. Cl. H01L 23/34

(52) U.S. Cl. 257/724

(57) ABSTRACT

According to one embodiment, there is provided a printed-wiring board with a built-in component including a first base material including a pattern forming surface on which a plurality of conductive patterns are formed. A circuit component is mounted on the pattern forming surface of the first base material, and is connected to the conductive patterns of the first base material. A filling material is stacked on the pattern forming surface of the first base material, and fills in a gap between the circuit component and the pattern forming surface. A second base material is stacked on the pattern forming surface of the first base material by interposing the filling material between the pattern forming surface and the second base material.

### CROSS-REFERENCE TO RELATED APPLICATIONS

This application is based upon and claims the benefit of priority from Japanese Patent Application No. 2006-051527, filed Feb. 28, 2006, the entire contents of which are incorporated herein by reference.

### BACKGROUND

1. Field

One embodiment of the invention relates to a printed-wiring board with a built-in component including a chip component provided in an electronic circuit, a manufacturing method of a printed-wiring board with a built-in component, and an electronic device using a printed-wiring board.

2. Description of the Related Art

Printed-wiring boards used in electronic circuit devices include a printed-wiring board with a built-in component including a chip component provided in an electronic circuit. As for such a kind of printed-wiring board with a built-in component, there is a wiring board with a built-in electronic component in which an opening is formed in a wiring board of an inner-layer, arranging an electronic component in the opening, stacking wiring boards, and filling a resin adhesive between the stacked wiring boards (see, for example, Japanese Patent Application KOKAI Publication No. 2005-191156).

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIGS. 1A, 1B, 1C, 1D and 1E are exemplary cross-sectional views showing manufacturing processes and an exemplary structure of a printed-wiring board with a built-in component according to a first embodiment of the invention;

FIG. 2 is a plan view showing a manufacturing process of the printed-wiring board with the built-in component according to the first embodiment;

FIGS. 3A, 3B, 3C, 3D and 3E are exemplary cross-sectional views showing manufacturing processes and an exemplary structure of a printed-wiring board with a built-in component according to a second embodiment of the invention;

FIGS. 4A, 4B, 4C, 4D and 4E are exemplary cross-sectional views showing manufacturing processes and an exemplary structure of a printed-wiring board with a built-in component according to a third embodiment of the invention;

FIGS. 5A, 5B and 5C are cross-sectional views showing variations of a printed-wiring board with the built-in component obtained by stacking the printed-wiring boards according to the first through third embodiments of the invention;

FIG. 6 is a cross-sectional view showing an exemplary structure of a printed-wiring board with a built-in component according to a fourth embodiment of the invention;

FIGS. 7A, 7B, 7C, 7D and 7E are cross-sectional views showing more detailed manufacturing processes of the printed-wiring board with the built-in component according to the first embodiment;

FIGS. 7F, 7G, 7H and 7I are cross-sectional views showing more detailed manufacturing processes of the printed-wiring board with the built-in component according to the first embodiment;

FIGS. 7J, 7K and 7L are cross-sectional views showing more detailed manufacturing processes of the printed-wiring board with the built-in component according to the first embodiment; and

FIG. 8 is a perspective view of an outside structure of an electronic device according to an embodiment of the invention.

### DETAILED DESCRIPTION

Various embodiments according to the invention will be described hereinafter with reference to the accompanying drawings. In general, according to one embodiment of the invention, a printed-wiring board with a built-in component includes: a first base material including a pattern forming surface on which a plurality of conductive patterns are formed; a circuit component mounted on the pattern forming surface of the first base material and connected to the conductive patterns of the first base material; a filling material which is stacked on the pattern forming surface of the first base material, and fills in a gap between the circuit component and the pattern forming surface; and a second base material stacked on the pattern forming surface of the first base material by interposing the filling material between the pattern forming surface and the second base material.

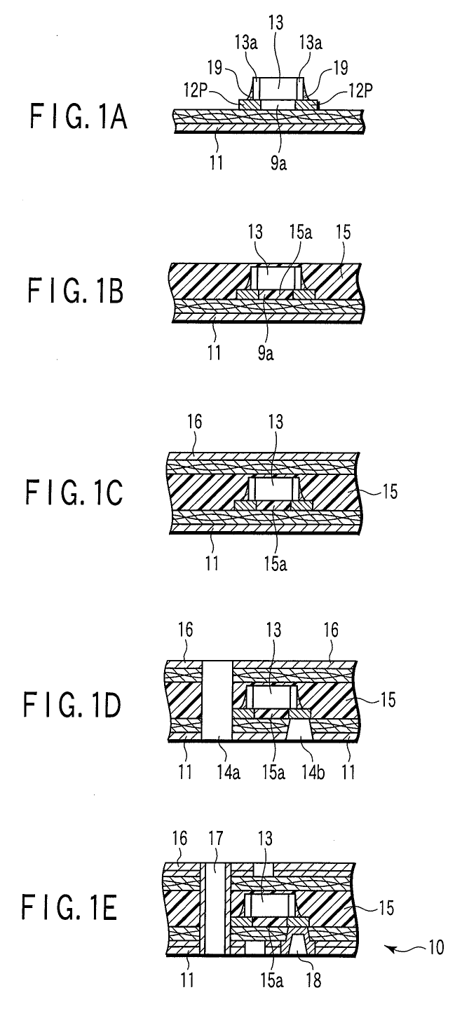

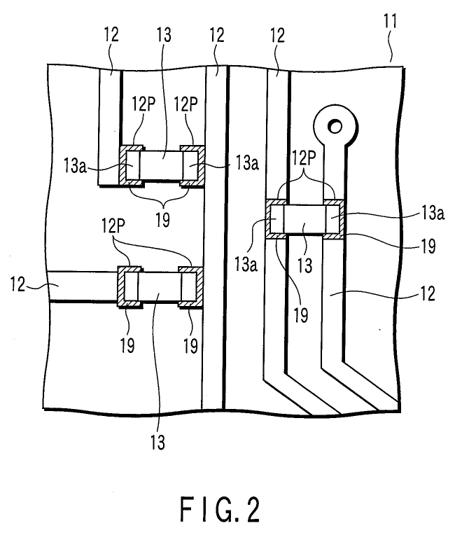

Referring to FIGS. 1A through 2, a description is given of a printed-wiring board with a built-in component according to a first embodiment of the invention, together with manufacturing processes of the printed-wiring board with the built-in component.

FIGS. 1A through 1E show manufacturing processes of the printed-wiring board with the built-in component according to the first embodiment of the invention. FIG. 1E shows an exemplary structure of the printed-wiring board with the built-in component according to the first embodiment of the invention, which board is a resulting product manufactured by the manufacturing processes. FIG. 2 shows an exemplary implementation of a circuit component in the process of FIG. 1A.

As shown in FIG. 1E, a printed-wiring board 10 with a built-in component includes a first base material 11, a circuit component 13, a filling material 15, and a second base material 16 which serves as another member.

The first base material 11 is a core member formed by using a sheet prepreg as an insulating body and providing a copper foil on both sides of the insulating body. The first base material 11 includes a conductive layer, forming a conductive pattern, on both surface side and inner-layer side. A conductive pattern 12 is formed on an inner-layer side pattern forming surface of the first base material 11. A component mounting surface 12P is formed at a predetermined circuit component mounting position of the conductive pattern 12.

The circuit component 13, which is connected to the component mounting surface 12P of the conductive pattern 12, is a chip component formed by a rectangular solid or a cylinder-like component body provided with a pair of electrodes 13a, 13a. Examples of a chip component used in this embodiment include a passive element such as a capacitor, a resistor element, etc. However, the chip component is not limited to the passive element, and an active element including two or more terminals and a particular operation/function may be used.

The filling material 15 is a thermosetting resin having a viscosity lower than that of the prepreg which is used to form the above-mentioned first base material 11 and the second base material 16. A gap 9a having a height of, for example, about 18 micrometers is formed between a bottom surface of the circuit component 13, which is connected to the component mounting surface 12 of the conductive pattern 12, and the pattern forming surface of the base material 11 on which the circuit component 13 is mounted. It is required that the viscosity of the filling material 15 is low enough to fill in the gap 9a by capillary phenomenon and pressure after stacking, and can fill in the gap 9a such that no air gap is formed in the gap 9a. The filling material 15 having a desired low viscosity can be obtained by, for example, mixing a filling material in a commercially available epoxy resin material having an extremely low viscosity, and adjusting the amount of the filling material to be mixed.

The second base material 16 is formed by using a sheet prepreg as an insulating body, and stacking a copper foil on one side of the insulating body, thereby forming a conductive pattern on a surface side of the insulating body. In addition to the above-mentioned material, various materials may be applied to the second base material 16. For example, the second base material 16 may include a structure in which only an insulating layer formed by using a prepreg is stacked on the filling material 15, a structure where a core member or a copper foil with resin is further stacked on the prepreg, etc.

In a first process shown in FIG. 1A, the pair of electrodes 13a, 13a of the circuit component 13 are soldered, with a solder 19, to the component mounting surface 12P of the conductive pattern 12 which is provided on the first base material 11. In this manner, the circuit component 13 is mounted on the pattern forming surface of the first base material 11.

In a second process shown in FIG. 1B, the gap 9a, which is formed between the circuit component 13 and the pattern forming surface of the first base material 11 on which the circuit component 13 is mounted, is impregnated with the filling material 15. The gap 9a can be impregnated with the filling material 15 by using a screen printing method, a curtain coating method, or a roll coating method. In this manner, the gap 9a is filled with the filling material 15, and the filling material 15 forms an insulating layer, having a thickness sufficient to cover the circuit component 13, on the pattern forming surface of the first base material 11. Consequently, the insulating layer, which is made of the filling material 15 having a thickness sufficient to cover the circuit component 13, is stacked and formed on the first base material 11. In FIGS. 1B through 1E, the filling material 15 filling the gap 9a is indicated by a reference numeral 15a.

In a third process shown in FIG. 1C, the second base material 16 is stacked on the pattern forming surface of the base material 11 on which the circuit component 13 is mounted, by interposing the insulating layer formed by the filling material 15 between the first base material 11 and the second base material 16. The above-mentioned members are integrated by heating/pressurizing the stacked members. In this manner, two insulating layers made of different materials, i.e., the filling material 15 and the second base material 16, are stacked and formed on the first base material 11. It should be noted that the above-mentioned heating process is not limited to once. For example, a heating process (curing) may be performed at the time of formation of the layer made of the filling material 15, at the time of formation of a layer on the filling material 15, and at the time of formation of a layer made of a core material or a copper foil with resin and formed on the layer on the filling material 15.

In a fourth process shown in FIG. 1D, boring is performed by drilling or laser processing on the printed-wiring board 10 in which the above-mentioned members are integrated. In this manner, a through-hole, a via hole, etc. are formed which connect conductive patterns between the layers. An opening bored by this process for forming a through-hole is indicated by a reference numeral 14a, and an opening for forming a via hole is indicated by a reference numeral 14b.

In a fifth process shown in FIG. 1E, a through-hole 17 and a via hole 18 are formed by performing plating and patterning on each of the holes (14a, 14b) bored in the fourth process and the surface layer of each of the first base material 11 and the second base material 16. In this manner, a circuit wiring pattern is formed which is used in an electronic device using the printed-wiring board 10. Consequently, the printed-wiring board 10 is realized in which the circuit wiring pattern, which is used in an electronic device, is formed.

In this printed-wiring board 10, the gap 9a, which is formed between the circuit component 13 and the pattern forming surface of the first base material 11 on which the circuit component 13 is mounted, is impregnated with the filling material 15. In other words, the gap 9a is filled with the filling material 15. Hence, no air pocket is formed. That is, an air pocket does not exist between the first base material 11 on which the circuit component 13 is mounted and the second base material 16 which is stacked on the first base material 11. Accordingly, it is possible to eliminate possibilities that the air (or gas) accumulated in an air pocket is thermally expanded and causes separation of a conductive pattern, damage to a chip component, disconnection of circuits, degradation of rigidity of a substrate, etc., even if the printed-wiring board 10 is heated by, for example, a heating process at the time of manufacturing of a substrate or heat reception after incorporation into an electronic device. Additionally, it is possible to further increase the rigidity of the entire substrate since two insulating layers made of different materials are formed on the first base material 11.

Accordingly, it is possible to provide a highly reliable printed-wiring board 10. In addition, it is possible to provide a highly reliable electronic device incorporating the printed-wiring board 10.

Additionally, it is possible to realize a highly rigid printed-wiring board 10 with a reinforced first base material 11 by using, instead of the prepreg, a reinforcing member (e.g., a rigid substrate) having a high rigidity for the second base material 16.

In the above-mentioned first embodiment, the insulating layer having a thickness sufficient to cover the circuit component 13 is formed by the filling material 15. However, provided that the gap 9a is filled with the filling material 15 and no air pocket is formed, the thickness of the insulating layer made of the filling material 15 may be, for example, a thickness sufficient to cover the circuit component 13 except for a portion of the circuit component 13. In this case, the second base material 16, which is stacked on the insulating layer made of the filling material 15, may include a structure where the second base material 16 is provided with a concave or a hole corresponding to the exposed portion of the circuit component 13, such that the insulating layer of the second base material covers the exposed portion of the circuit component 13. However, in such a structure, in order to avoid formation of an air pocket in a portion covering the exposed portion of the circuit component 13, it is necessary to impregnate the portion covering the exposed portion of the circuit component 13 with the filling material 15, other insulating material (or an adhesive), etc.

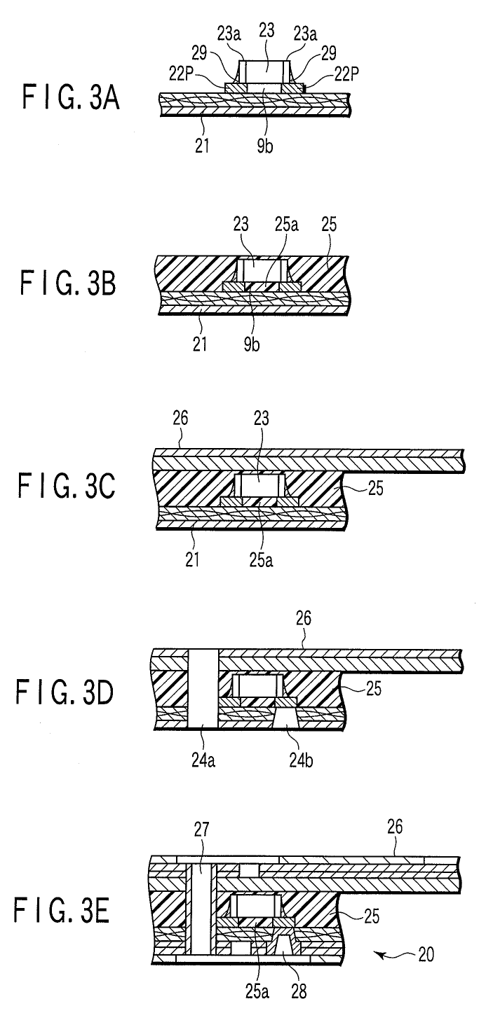

Referring to FIGS. 3A through 3E, a description is given of a printed-wiring board with a built-in component according to a second embodiment of the invention, together with manufacturing processes of the printed-wiring board. FIG. 3E shows an exemplary structure of the printed-wiring board according to the second embodiment of the invention, which is a resulting product manufactured by the manufacturing processes. A printed-wiring board 20 with a built-in component according to the second embodiment includes a first base material 21, a circuit component 23, a filling material 25, and a second base material 26 which serves as another member. The first base material 21, the circuit component 23, and the filling material 25 in the second embodiment are similar to the first base material 11, the circuit component 13, and the filling material 15 of the first embodiment shown in FIGS. 1A through 1E, respectively, and a detailed description thereof will be omitted. The second base material 26, which serves as another member, is a flexible substrate using a flexible material. A part of an insulating layer of the flexible substrate 26 is stacked on the filling material 25.

In a first process shown in FIG. 3A, the circuit component 23 is mounted on a pattern forming surface of the first base material 21 by soldering electrodes 23a of the circuit component 23 with a solder 29 on a component mounting surface 22P of a conductive pattern provided to the first base material 21.

In a second process shown in FIG. 3B, a gap 9b, which is formed between the circuit component 23 and the pattern forming surface of the first base material 21 on which the circuit component 23 is mounted, is impregnated with the filling material 25. In this manner, the gap 9 is filled with the filling material 25. The filling material 25 forms an insulating layer, having a thickness sufficient to cover the circuit component 23, on the pattern forming surface of the first base material 21. Consequently, the insulating layer formed by the filling material 25 and having a thickness sufficient to cover the circuit component 23 is stacked and formed on the first base material 21. In FIGS. 3B, 3C and 3E, the filling material 25 filling the gap 9b is indicated by a reference numeral 25a.

In a process 3 shown in FIG. 3C, a part of the insulating layer of the flexible substrate 26, forming the second base material, is stacked on the pattern forming surface of the first base material 21 on which the circuit component 23 is mounted, by interposing the insulating layer formed by the filling material 25 between the flexible substrate 26 and the first base material 21. The above-mentioned members are integrated by heating/pressurizing the stacked members. In this manner, two insulating layers made of different materials, i.e., the filling material 25 and the second base material 26, are stacked and formed on the first base material 21.

In a fourth process shown in FIG. 3D, holes 24a and 24b are bored in the printed-wiring board 20 in which the above-mentioned members are integrated. The holes 24a and 24b are bored by drilling or laser processing for forming a through-hole, a via hole, etc., which connect circuits of conductive patterns of the layers.

In a fifth process shown in FIG. 3E, plating and patterning are performed on each of the holes 24a and 24b bored in the fourth process and each surface layer of the first base material 21 and the second base material 26. In this manner, a through-hole 27 and a via hole 28 are formed, and a circuit wiring pattern is formed which is used in an electronic device using the printed-wiring board 20. Consequently, the printed-wiring board 20 is realized which includes the integrated flexible substrate including the circuit wiring pattern used in the electronic device.

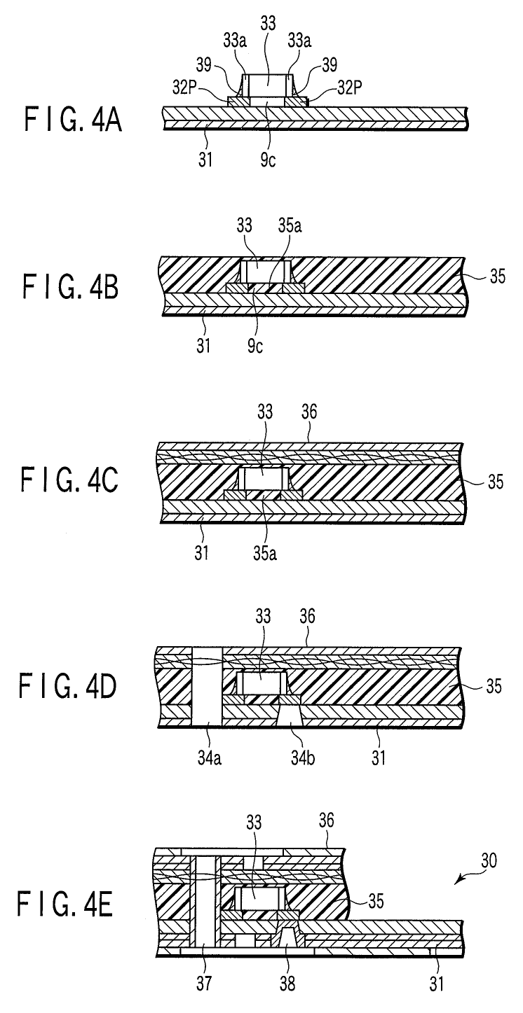

Referring to FIGS. 4A through 4E, a description is given of a printed-wiring board with a built-in component according to a third embodiment of the invention, together with manufacturing processes of the printed-wiring board. FIG. 4E shows an exemplary structure of the printed-wiring board with the built-in component according to the third embodiment of the invention, which is a resulting product manufactured by the manufacturing processes. A printed-wiring board 30 with a built-in component according to the third embodiment includes a first base material 31, a circuit component 33, a filling material 35, and a third base material 36 which serves as another member. The circuit component 33, the filling material 35, and the second base material 36 in the third embodiment are similar to the circuit component 13, the filling material 15, and the second base material 16 in the first embodiment shown in FIGS. 1A through 1E, respectively, and a detailed description thereof will be omitted. The first base material 31 is a flexible substrate using a flexible material. The circuit component 33 is mounted and the filling material 35 is stacked on a part of an insulating layer of the flexible substrate 31.

In a first process shown in FIG. 4A, electrodes 33a of the circuit component 33 are soldered, by a solder 39, to a component mounting surface 32P of a conductive pattern provided in a part of the insulating layer of the flexible substrate 31. In this manner, the circuit component 33 is mounted on a pattern forming surface of the flexible substrate 31.

In a second process shown in FIG. 4B, a gap 9c, which is formed between the circuit component 33 and the pattern forming surface of the flexible substrate 31 on which the circuit component 33 is mounted, is impregnated with the filling material 35. In other words, the gap 9c is filled with the filling material 35. The filling material 35 forms an insulating layer having a thickness sufficient to cover the circuit component 33 on the pattern forming surface of the flexible substrate 31. Accordingly, the insulating layer formed by the filling material 35 and having a thickness sufficient to cover the circuit component 33 is stacked and formed on the pattern forming surface of the flexible substrate 31. In FIGS. 4B and 4C, the filling material 35 filling the gap 9c is indicated by a reference numeral 35a.

In a third process shown in FIG. 4C, the second base material 36 is stacked on the pattern forming surface of the flexible substrate 31 on which the circuit component 33 is mounted, by interposing the insulating layer formed by the filling material 35 between the second base material 36 and the pattern forming surface of the flexible substrate 31. The above-mentioned members are integrated by heating/pressurizing the stacked members. In this manner, two insulating layers made of different materials, i.e., the filling material 35 and the second base material 36, are formed on the first base material 31.

In a fourth process shown in FIG. 4D, holes 34a and 34b are bored in the printed-wiring board 30 in which the above-mentioned members are integrated. The holes 34a and 34b are bored by drilling or laser processing for forming a through-hole, a via hole, etc., which connect circuits of conductive patterns of the layers.

In a fifth process shown in FIG. 4E, plating and patterning are performed on each of the holes 34a and 34b bored in the fourth process and each surface layer of the flexible substrate 31, forming the first base material 31, and the second base material 36. In this manner, a through-hole 37 and a via hole 38 are formed, and a circuit wiring pattern is formed which is used in an electronic device using the printed-wiring board 30. Consequently, the printed-wiring board 30 is realized which includes the integrated flexible substrate including the circuit wiring pattern used in the electronic device.

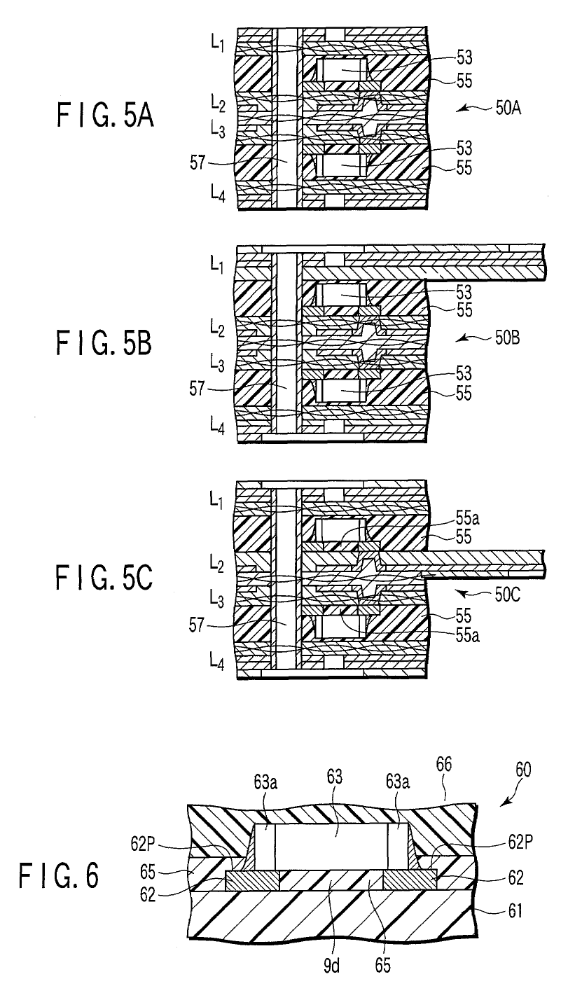

FIGS. 5A, 5B and 5C show variations of the printed-wiring boards according to the first, second and third embodiments, respectively.

FIG. 5A shows an exemplary structure of a printed-wiring board 50A with built-in components having four layers (L1, L2, L3 and L4). The printed-wiring board 50A is realized by stacking the printed-wiring boards 10 according to the first embodiment shown in FIGS. 1A through 1E.

FIG. 5B shows an exemplary structure of a printed-wiring board 50B with built-in components having four layers (L1, L2, L3 and L4). The printed-wiring board 50B is realized by stacking the printed-wiring boards 10 according to the first embodiment shown in FIGS. 1A through 1E and the printed-wiring boards 20 according to the second embodiment shown in FIGS. 3A through 3E.

FIG. 5C shows an exemplary structure of a printed-wiring board 50C with built-in components having four layers (L1, L2, L3 and L4). The printed-wiring board 50C is realized by stacking the printed-wiring boards 10 according to the first embodiment shown in FIGS. 1A through 1E and the printed-wiring boards 30 according to the third embodiment shown in FIGS. 4A through 4E. In FIGS. 5A through 5C, circuit components are indicated by a reference numeral 53, filling materials are indicated by a reference numeral 55 (55a), and through-holes are indicated by a reference numeral 57.

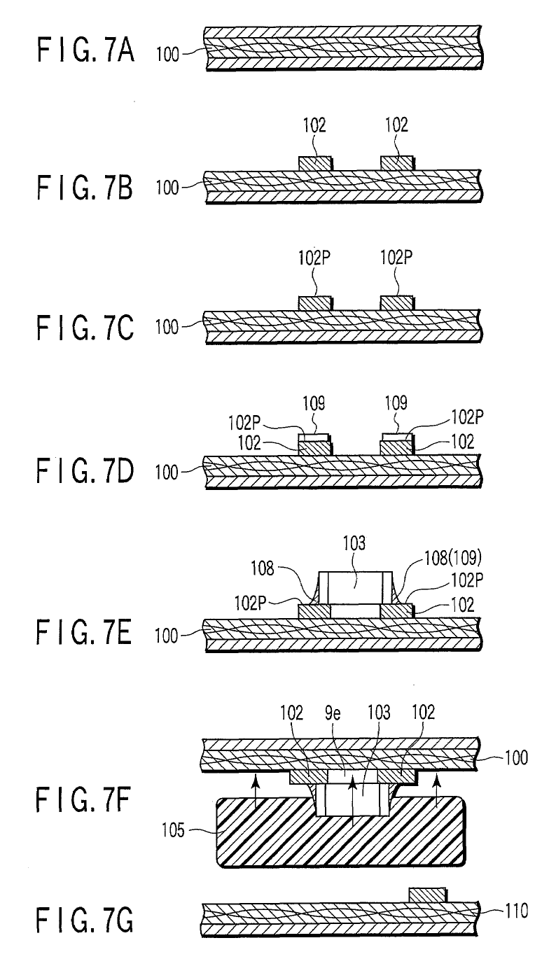

FIG. 6 shows a fourth embodiment of the invention. In each of the above-mentioned first, second and third embodiments, the insulating layer having the thickness sufficient to cover the circuit component (13, 23, 33) is formed by the filling material (15, 25, 35). In the fourth embodiment shown in FIG. 6, electrodes 63a of a circuit component 63 are soldered to a component mounting surface 62P of a conductive pattern 62 provided on a first base material 61. In this manner, the circuit component 63 is mounted on a pattern forming surface of the first base material 61. A gap 9d, which is formed between the circuit component 63 and the pattern forming surface of the first base material 61 on which the circuit component 63 is mounted, is impregnated with a filling material 65. In other words, the gap 9d is filled with the filling material 65. The filling material 65 forms an insulating layer, having a thickness sufficient to cover the circuit component 63 except for a portion of the circuit component 63, on the pattern forming surface of the first base material 61. A second base material 66 is stacked on the insulating layer formed by the filling material 65. With such a structure, the thickness of the insulating layer is reduced, and thus the thickness of the entire substrate is reduced. Thus, it is possible to realize a printed-wiring board 60 with a built-in component for which a stable and highly reliable circuit operation can be expected.

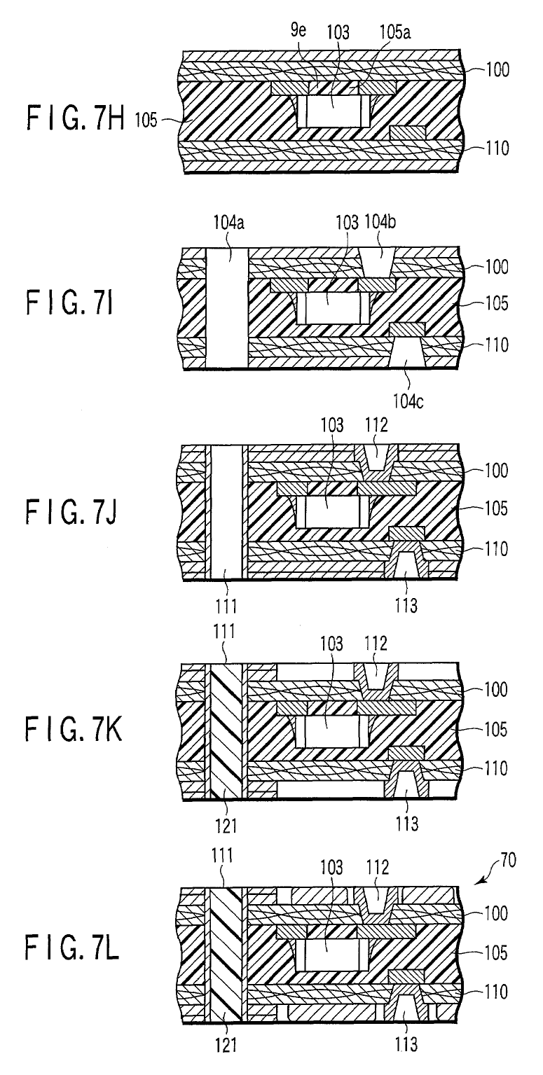

FIGS. 7A through 7L show more detailed manufacturing processes of the printed-wiring board with the built-in component according to the above-mentioned first embodiment. FIG. 7L shows a printed-wiring board 70 with a built-in component manufactured by these manufacturing processes. The printed-wiring board 70 includes a first base material 100, a circuit component 103, a filling material 105, and a second base material 110.

In a first process shown in FIG. 7A, a core material obtained by forming a conductive layer on both sides of a sheet prepreg is prepared as the first base material 100. In a second process shown in FIG. 7B, an etching process is performed on one side (a pattern forming surface on an inner side after stacking) of the first base material 100 to form a conductive pattern 102 on which a built-in circuit component is to be mounted. In a third process shown in FIG. 7C, surface treatment suitable for a conductive paste is performed on component mounting surfaces 102P of the conductive patterns 102 which are formed by the etching process. In a fourth process shown in FIG. 7D, a conductive paste 109 is printed on the component mounting surfaces 102P of the conductive patterns 102.

In a fifth process shown in FIG. 7E, the circuit component 103 is arranged, via the conductive paste 109, on the component mounting surface 102P of the conductive pattern 102 formed on the first base material 100. Electrodes of the circuit component 103 are soldered to the component mounting surface 102P by a reflow process, and the circuit component 103 is mounted on the pattern forming surface of the first base material 100.

In a sixth process shown in FIG. 7F, a gap 9e, which is formed between the circuit component 103 and the pattern forming surface of the first base material 100 on which the circuit component 103 is mounted, is impregnated with the filling material 105. In other words, the gap 9e is filled with the filling material 105. The filling material 105 forms an insulating layer, having a thickness sufficient to cover the circuit component 103, on the pattern forming surface of the first base material 100. It should be noted that FIG. 7F shows a state before filling of the filling material 105.

In a seventh process shown in FIG. 7G, the second base material 110 is prepared by forming a conductive layer on both sides of a sheet prepreg. The conductive pattern is formed by performing an etching process on one side of the second base material 110.

In an eighth process shown in FIG. 7H, the second base material 110 is stacked on the pattern forming surface of the first base material 100 on which the circuit component 103 is mounted, by interposing the insulating layer formed by the filling material 105 between the second base material 110 and the pattern forming surface of the first base material 100. The above-mentioned members are integrated by heating/pressurizing the stacked members.

In a ninth process shown in FIG. 7I, a hole 104a for forming a through-hole and holes 104b and 104c for forming via holes, etc. are bored in the printed-wiring board in which the above-mentioned members are integrated. The holes 104a, 104b and 104c are bored by drilling or laser processing. The holes 104a, 104b and 104c connect circuits of conductive patterns of the layers.

In a tenth process shown in FIG. 7J, plating is performed on each of the holes 104a, 104b and 104c bored in the ninth process and each surface layer of the first base material 100 and the second base material 110. In this manner, a through-hole 111 and via holes 112 and 113 are formed. In an eleventh process shown in FIG. 7K, patterning and a process for filling in the holes by a solder 121 are performed. In a twelfth process shown in FIG. 7L, solder resist processing is performed on the pattern forming surfaces of the surface layers.

It should be noted that, in the processes shown in FIGS. 7A through 7L, the pattern forming process and the processes after integration of the stacked members are not limited to the processes in the above-mentioned embodiment, and may be performed in accordance with existing substrate manufacturing techniques.

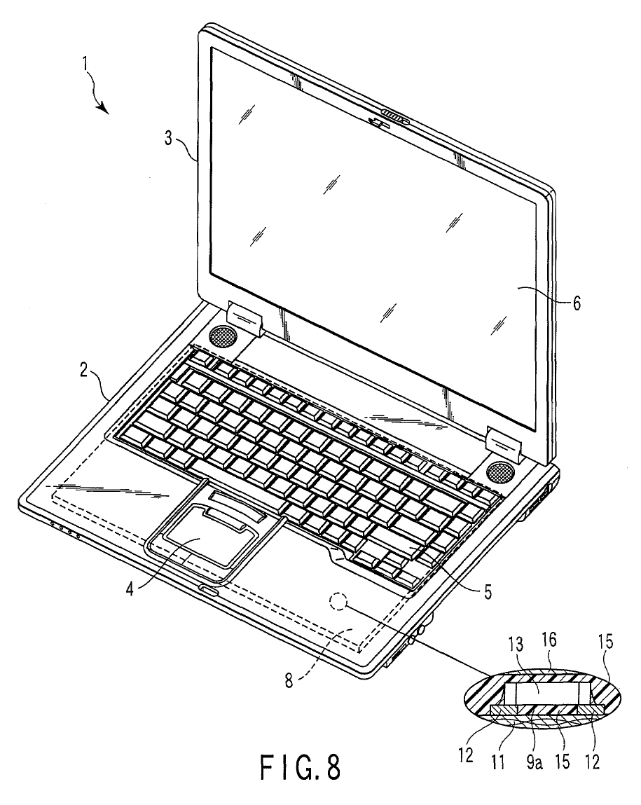

FIG. 8 shows an exemplary structure of an electronic device mounting a printed-wiring board with a built-in component manufactured in accordance with one of the above-mentioned embodiments. FIG. 8 shows an exemplary case where the printed-wiring board 10 according to the first embodiment is mounted on a compact electronic device such as a portable computer.

In FIG. 8, a display housing 3 is rotatably attached to a main body 2 of a portable computer 1 via a hinge mechanism. The main body 2 is provided with operation units such as a pointing device 4, a keyboard 5, etc. The display housing 3 is provided with a display device 6 such as a LCD, etc.

Additionally, the main body 2 is provided with a printed-circuit board (mother board) 8 on which a control circuit is mounted. The control circuit controls the display device 6 and the operation units such as the pointing device 4, the keyboard 5, etc. The printed-circuit board (mother board) 8 is realized by using the printed-wiring board 10 according to the first embodiment shown in FIGS. 1A through 1E.

In the printed-wiring board 10 used for the printed-circuit board (mother board) 8, the gap 9a, which is formed between the circuit component 13 and the pattern forming surface of the first base material 11 on which the circuit component 13 is mounted, is impregnated with the filling material 15. Thus, since the gap 9a is filed with the filling material 15, an air pocket does not exist inside the substrate. Accordingly, it is possible to eliminate possibilities that the air (or gas) accumulated in an air pocket is thermally expanded and causes separation of a conductive pattern, damage to a chip component, disconnection of circuits, degradation of rigidity of a substrate, etc., even if the printed-wiring board 10 is heated by, for example, a heating process at the time of manufacturing of a substrate or heat reception after incorporation into the electronic device. Additionally, since the circuit component 13 is incorporated in the substrate in advance, it is possible to perform high-density packaging of an electronic circuit, to reduce and adjust the length of wiring, and to improve electric characteristic including a high-frequency property. Hence, it is possible to provide a portable computer for which a highly reliable and stable operation can be expected.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed-wiring board with a built-in component, comprising:
a first base material including a pattern forming surface on which a plurality of conductive patterns are formed;
a circuit component mounted on the pattern forming surface of the first base material and connected to the conductive patterns of the first base material;
a filling material which is stacked on the pattern forming surface of the first base material, and fills in a gap between the circuit component and the pattern forming surface; and
a second base material stacked on the pattern forming surface of the first base material by interposing the filling material between the pattern forming surface and the second base material.

2. The printed-wiring board according to claim 1, wherein the filling material and the second base material form insulating layers.

3. The printed-wiring board according to claim 2, wherein the filling material forms one of the insulating layers having a thickness sufficient to cover the circuit component.

4. The printed-wiring board according to claim 2, wherein the filling material forms one of the insulating layers having a thickness sufficient to cover the circuit component except for a portion of the circuit component.

5. The printed-wiring board according to claim 1, wherein the second base material includes a reinforcing member for reinforcing rigidity of the first base material.

6. The printed-wiring board according to claim 1, wherein the circuit component includes a passive element connected to the conductive patterns.

7. A manufacturing method of a printed-wiring board with a built-in component in which a circuit component is provided between conductive patterns formed on a pattern forming surface of a first base material, the manufacturing method comprising:
impregnating, with a filling material, a gap between the circuit component and the pattern forming surface of the first base material on which the circuit component is mounted;
stacking the filling material on the pattern forming surface of the first base material; and
stacking a second base material on the pattern forming surface of the first base material by interposing the filling material between the pattern forming surface and the second base material, and thereafter heating and pressurizing the first base material, the filling material, and the second base material, thereby integrating the first base material, the filling material, and the second base material.

8. The manufacturing method according to claim 7, wherein the filling material and the second base material form insulating layers.

9. The manufacturing method according to claim 8, wherein the filling material forms one of the insulating layers having a thickness sufficient to cover the circuit component.

10. The manufacturing method according to claim 8, wherein the second base material is a part of a flexible substrate, and a part of one of the insulating layers of the flexible substrate is stacked on the filling material.

11. The manufacturing method according to claim 8, wherein the second base material is a part of a rigid substrate, and a part of one of the insulating layers of the rigid substrate is stacked on the filling material.

12. The manufacturing method according to claim 7, wherein the gap is impregnated with the filling material by a screen printing method.

13. The manufacturing method according to claim 7, wherein the gap is impregnated with the filling material by a curtain coating method.

14. The manufacturing method according to claim 7, wherein the gap is impregnated with the filling material by a roll coating method.

15. An electronic device, comprising:
a display unit;
an operation unit; and
a circuit board incorporating therein a control circuit which controls an operation of one of the display unit and the operation unit,
the circuit board including:
a first base material including a pattern forming surface on which a plurality of conductive patterns are formed;
a circuit component mounted on the pattern forming surface of the first base material and connected to the conductive patterns of the first base material;
a filling material stacked on the pattern forming surface of the first base material and filling in a gap between the circuit component and the pattern forming surface on which the circuit component is mounted; and
a second base material stacked on the pattern forming surface of the first base material by interposing the filling material between the pattern forming surface and the second base material.
